(19) United States
(12) Patent Application Publication
(10) Pub. No.: US 2024/0250076 A1
(43) Pub. Date: Jul. 25, 2024

(54) ELECTRONIC DEVICE

(71) Applicant: Innolux Corporation, Miaoli County (TW)

(72) Inventors: Kuang-Pin Chao, Miaoli County (TW); Min-Han Tsai, Miaoli County (TW); Hao-Jung Huang, Miaoli County (TW)

(73) Assignee: Innolux Corporation, Miaoli County (TW)

(21) Appl. No.: 18/402,766

(22) Filed: Jan. 3, 2024

Related U.S. Application Data
(60) Provisional application No. 63/439,863, filed on Jan. 19, 2023.

(30) Foreign Application Priority Data
Sep. 15, 2023 (CN) 202311194984.7

(51) Int. Cl. H01L 25/16

(52) U.S. Cl. CPC H01L 25/162; H01L 25/167

(57) ABSTRACT

An electronic device includes a first curved module and a second curved module. The first curved module includes a first electronic element and a first curved unit. The second curved module is spliced to one side of the first curved module and includes a second electronic element and a second curved unit. The first curved unit and the second curved unit include curved surfaces.

### CROSS-REFERENCE TO RELATED APPLICATION

This application claims the priority benefits of U.S. provisional application Ser. No. 63/439,863, filed on Jan. 19, 2023, and China application Ser. No. 202311194984.7, filed on Sep. 15, 2023. The entirety of each of the above-mentioned patent applications is hereby incorporated by reference herein and made a part of this specification.

### BACKGROUND

### Technical Field

The disclosure relates to an electronic device.

### Description of Related Art

In most of the current splicing displays, a flexible light panel provided with a magnet on the back is attached to a curved bracket to obtain the required curved shape. However, the flexible light panel is very likely to become recessed due to magnetic adsorption in the area where the magnet is provided, which causes as a negative impact on the display quality.

### SUMMARY

The present disclosure provides an electronic device with good display quality.

In an embodiment of the disclosure, an electronic device includes a first curved module and a second curved module. The first curved module includes a first electronic element and a first curved unit. The second curved module is spliced to one side of the first curved module and includes a second electronic element and a second curved unit. The first curved unit and the second curved unit include curved surfaces.

In another embodiment of the present disclosure, the electronic device includes N curved modules, a fixing bracket and a plurality of fasteners. N is a positive integer greater than 2. The N curved modules include electronic elements and curved units, and the curved units include curved surfaces and plane surfaces. Each plane surface is fixed to the fixing bracket through at least one of a plurality of fasteners, and the N curved modules form an annular curved module.

In order to make the above-mentioned features and advantages of the present disclosure more clear and easy to understand, embodiments are given below and are described in detail below with reference to the accompanying drawings.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 is a schematic top view of an electronic device according to some embodiments of the present disclosure.

FIG. 2 and FIG. 3 are respectively two schematic cross-sectional views of an electronic element in FIG. 1.

FIG. 4 is a three-dimensional schematic view of a curved unit in FIG. 1.

FIG. 5 and FIG. 6 are respectively top views of curved modules according to other embodiments of the present disclosure.

FIG. 7 to FIG. 12 are schematic views of electronic devices according to other embodiments of the present disclosure.

### DESCRIPTION OF THE EMBODIMENTS

Reference will now be made in detail to the exemplary embodiments of the present disclosure, examples of which are illustrated in the accompanying drawings. Wherever possible, the same reference numbers are used in the drawings and descriptions to refer to the same or like parts.

Certain terms will be used throughout the specification and appended claims of this disclosure to refer to particular elements. Those skilled in the art should understand that electronic device manufacturers may refer to the same component by different names. The text does not intend to distinguish between those elements that have the same function but have different names. In the following description and claims, terms such as “comprising” and “including” are open-ended words, so they should be interpreted as meaning “including but not limited to . . . ”.

The directional terms mentioned herein, such as “upper”, “lower”, “front”, “rear”, “left”, “right”, etc., only refer to the directions of the accompanying drawings. Accordingly, the directional terms are used for illustration, not for limitation of the present disclosure. In the drawings, each figure illustrates the general characteristics of methods, structures and/or materials used in particular embodiments. However, these drawings should not be interpreted as defining or limiting the scope or nature encompassed by these embodiments. For example, the relative sizes, thicknesses and positions of layers, regions and/or structures may be reduced or exaggerated for clarity.

A structure (or layer, element, substrate) described in this disclosure is located on/over another structure (or layer, element, substrate), which can mean that the two structures are adjacent and directly connected, or it can mean that the two structures are adjacent rather than directly connected. Indirect connection means that there is at least one intermediate structure (or intermediate layer, intermediate element, intermediate substrate, intermediate space) between two structures, and the lower surface of a structure is adjacent to or directly connected to the upper surface of the intermediate structure. The upper surface of the other structure is adjacent to or directly connected to the lower surface of the intermediate structure. The intermediate structure can be composed of a single-layer or multi-layer physical structure or a non-physical structure, the disclosure is not limited thereto. In this disclosure, when a certain structure is set “on” other structures, it may mean that a certain structure is “directly” on other structures, or that a certain structure is “indirectly” on other structures, that is, there is at least one structure interposed between a certain structure and other structures.

The terms “about”, “equal to”, “equivalent to” or “identical”, “substantially” or “generally” are normally interpreted as being within 20% of a given value or range, or as being within 10%, 5%, 3%, 2%, 1%, or 0.5% of a given value or range. In addition, the description that “the range is from the first value to the second value” and “the range is between the first value and the second value” mean that the range includes the first value, the second value and other values therebetween.

Ordinal numbers used in the specification and claims, such as “first”, “second”, etc., are used to modify elements, which neither implies nor means that the (or these) elements are preceded by any ordinal numbers, nor indicates the order of a certain element with another element, or the order of the manufacturing method. The use of these ordinal numbers is only used to clearly distinguish the element with a certain name from another element with the same name. Different terms may be adopted in claims and the specification, accordingly, the first component in the description may be referred to as the second component in the claim.

The electrical connection or coupling described in this disclosure can refer to direct connection or indirect connection. In the case of direct connection, the terminals of the elements on the two circuits are directly connected or connected to each other with a conductor line segment. In the case of indirect connection, there are switches, diodes, capacitors, inductors, resistors, other suitable elements, or a combination of the above elements between the terminals of the elements on the two circuits, but not limited thereto.

In this disclosure, the thickness, length and width may be measured by optical microscope (OM), and the thickness or width may be obtained by measuring the cross-sectional image in the electron microscope, but the disclosure is not limited thereto. Additionally, any two values or directions used for comparison may have certain errors. In addition, the terms “equal to”, “equivalent to”, “same”, “substantially” or “generally” mentioned in the present disclosure generally mean that a value falls within 10% of a given value or range. Moreover, the phrase “a given range is between a first value and a second value”, “a given range falls within a range of a first value to a second value” or “a given range is between a first value and a second value” means that the given range includes the first value, the second value and other values therebetween. If the first direction is perpendicular to the second direction, the angle between the first direction and the second direction can be between 80 degrees and 100 degrees; if the first direction is parallel to the second direction, the angle between the first direction and the second direction may be between 0 degrees and 10 degrees.

Unless otherwise defined, all terms (including technical and scientific terms) used herein have the same meaning as commonly understood by one of ordinary skill in the art to which this disclosure belongs. It can be understood that these terms, such as those defined in commonly used dictionaries, should be interpreted as having meanings consistent with the background or context of the related technology and the present disclosure, and should not be interpreted in an idealized or overly formal manner, unless otherwise specified in the disclosed embodiments.

In the present disclosure, the electronic device may include a display device, a backlight device, an antenna device, a packaging device, a sensing device or a splicing device, but not limited thereto. The electronic device may be a bendable or flexible electronic device. The display device may be a non-self-luminous display device or a self-luminous display device. The display device may include, for example, liquid crystal, light-emitting diode, fluorescence, phosphor, quantum dot (QD), other suitable display media, or a combination thereof. The antenna device may include, for example, a frequency selective surface (FSS), a radio frequency filter (RF-Filter), a polarizer, a resonator or an antenna, etc. The antenna may be a liquid crystal type antenna or a varactor diode antenna. The sensing device may be a sensing device for sensing capacitance, light, thermal energy or ultrasonic waves, but not limited thereto. In the present disclosure, an electronic device may include electronic elements, and the electronic elements may include passive elements and active elements, such as capacitors, resistors, inductors, diodes, transistors, and the like. The diodes may include light-emitting diodes, varactor diodes or photodiodes. The light-emitting diode may include, for example, an organic light-emitting diode (OLED), a mini light-emitting diode (mini LED), a micro light-emitting diode (micro LED) or a quantum dot light-emitting diode (quantum dot LED), but not limited thereto. The splicing device may be, for example, a display splicing device or an antenna splicing device, but is not limited thereto. It should be noted that the electronic device can be any permutation and combination of the aforementioned, but not limited thereto. The packaging device may be suitable for wafer-level package (WLP) technology or panel-level package (WLP) technology, such as a chip first process or an RDL first process. In addition, the shape of the electronic device may be rectangular, circular, polygonal, with curved edges, or other suitable shapes. An electronic device may have peripheral systems such as a drive system, a control system, a light source system, . . . to support a display device, an antenna device, a wearable device (such as including augmented reality or virtual reality), a vehicle-mounted device (such as including a car windshield), or a splicing device.

It should be noted that, in the following embodiments, without departing from the spirit of the present disclosure, the features in several different embodiments can be replaced, reorganized, and mixed to complete other embodiments. As long as the features of the various embodiments do not violate the spirit of the disclosure or conflict with each other, they can be mixed and matched freely.

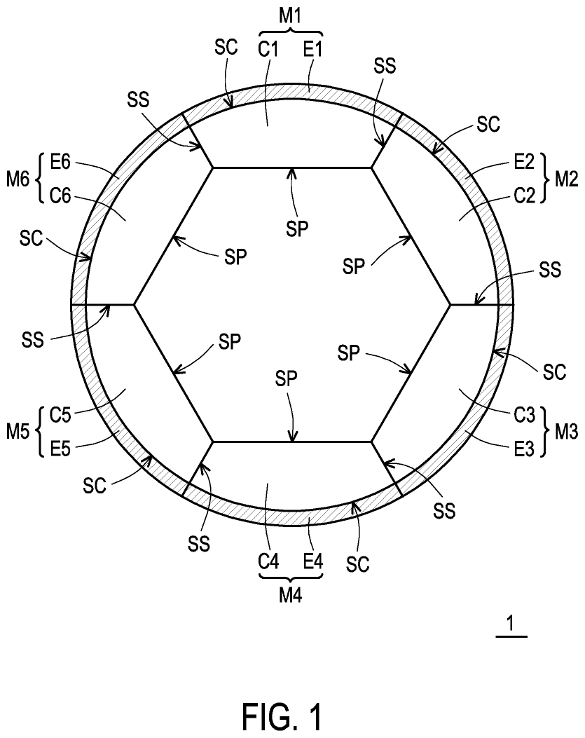

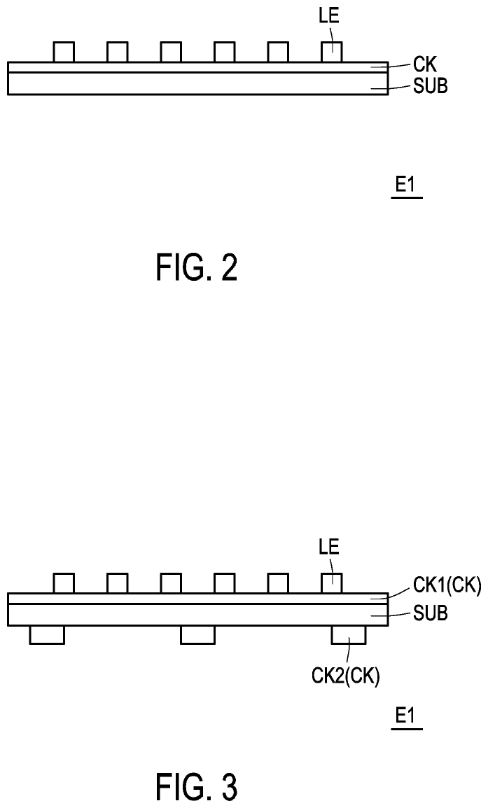

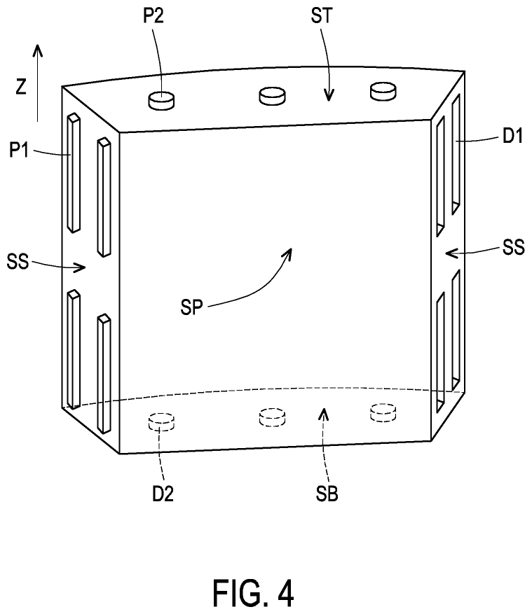

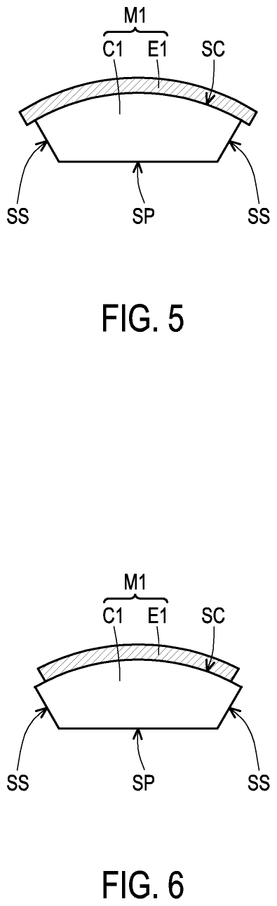

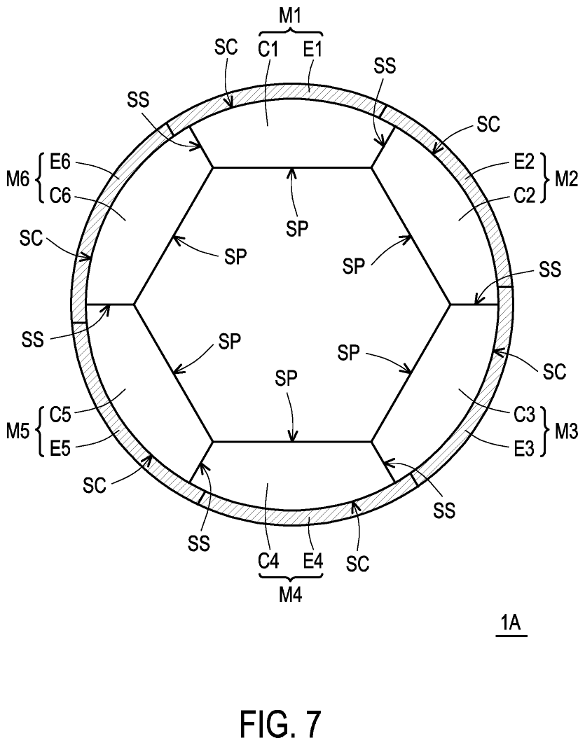

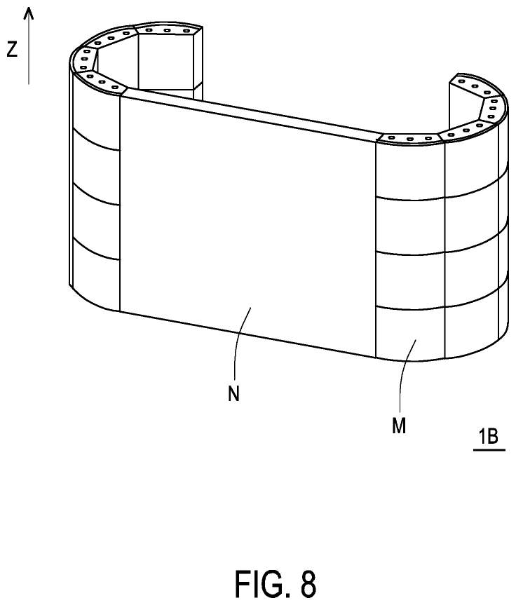

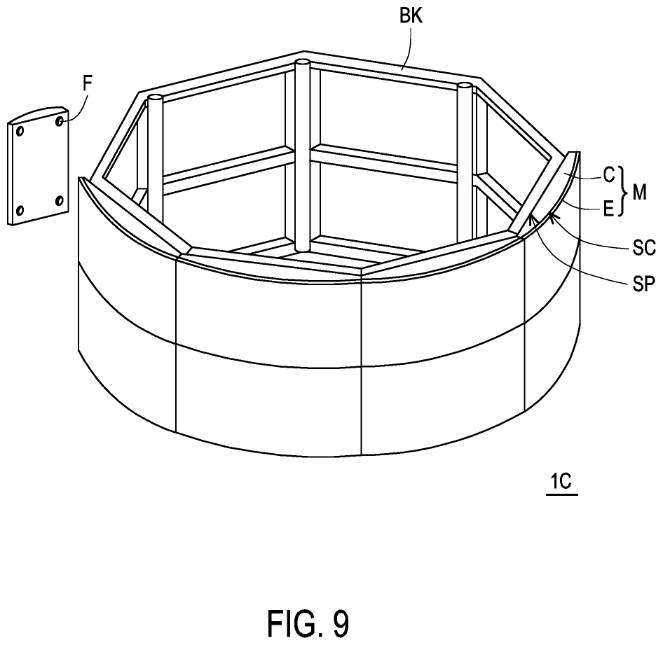

FIG. 1 is a schematic top view of an electronic device according to some embodiments of the present disclosure. FIG. 2 and FIG. 3 are respectively two schematic cross-sectional views of an electronic element in FIG. 1. FIG. 4 is a three-dimensional schematic view of a curved unit in FIG. 1. FIG. 5 and FIG. 6 are respectively top views of curved modules according to other embodiments of the present disclosure. FIG. 7 to FIG. 12 are schematic views of electronic devices according to other embodiments of the present disclosure. FIG. 7 and FIG. 10 to FIG. 12 are top views, and FIG. 8 and FIG. 9 are perspective views.

Referring to FIG. 1, the electronic device 1 may include a first curved module M1 and a second curved module M2. The first curved module M1 may include a first electronic element E1 and a first curved unit C1. The second curved module M2 is spliced to one side of the first curved module M1 and includes a second electronic element E2 and a second curved unit C2. The first curved unit C1 and the second curved unit C2 may include curved surfaces SC. Furthermore, the first curved unit C1 and the second curved unit C2 may be designed to include a curved surface SC and a plane surface SP. Moreover, each of the first curved unit C1 and the second curved unit C2 may also be designed to include a curved surface SC and a plane surface SP according to the design. In some embodiments (not shown), the curved module may include a curved unit and a plurality of electronic elements. For example, the first curved module M1 may include a first curved unit C1 and a plurality of first electronic elements E1, wherein the plurality of first electronic elements E1 may be disposed on the first curved unit C1. In another example, the first curved module M1 may include a first curved unit C1 and a plurality of first electronic elements E1, and the second curved module M2 may also include a second curved unit C2 and a plurality of second electronic elements E2, wherein the plurality of first electronic elements E1 may be disposed on the first curved unit C1, and the plurality of second electronic elements E2 may also be disposed on the second curved unit C2. In some embodiments, the electronic element in the curved module may be a flexible display. In some embodiments (not shown), as shown in FIG. 1, a printed circuit board may be disposed between the electronic element and the curved unit. Specifically, the electronic device 1 may be a splicing device, such as a display splicing device, but is not limited thereto. Multiple curved modules in the electronic device 1 are spliced together so that the spacing between the minimum display units (such as pixels) in adjacent curved modules remains consistent to achieve a large-area continuous display effect.

Please refer to FIG. 2 and FIG. 3 at the same time. The first electronic element E1 may include a flexible substrate SUB, a driving circuit CK and a plurality of light-emitting elements LE, wherein the driving circuit CK may be disposed on the same side as the plurality of light-emitting elements LE (as shown in FIG. 2) or on a different side from the multiple light-emitting elements LE (as shown in FIG. 3).

As shown in FIG. 2 or FIG. 3, the first electronic element E1 may include a flexible substrate SUB, a driving circuit CK and a plurality of light-emitting elements LE, wherein the driving circuit CK and a plurality of light-emitting elements LE are disposed on the flexible substrate SUB, and the plurality of light-emitting elements LE are electrically connected to the driving circuit CK. As shown in FIG. 3, the driving circuit CK may include a first driving circuit CK1 and a second driving circuit CK2. The first driving circuit CK1 is on the same side as the plurality of light-emitting elements LE, and the second driving circuit CK2 is on a different side from the plurality of light-emitting elements LE.

The material of the flexible substrate SUB includes, for example, glass or plastic, but is not limited thereto. Plastics may include polycarbonate (PC), polyimide (PI), polypropylene (PP), polyethylene terephthalate (PET), and other suitable flexible materials or combinations of the aforementioned materials, but not limited thereto. In addition, the light transmittance of the flexible substrate SUB is not limited, that is to say, the flexible substrate SUB may be a light-transmissive substrate, a semi-transparent substrate or an opaque substrate.

The driving circuit CK may include an active device array or a driving chip. Taking the active device array as an example (such as the driving circuit CK in FIG. 2; the first driving circuit CK1 in FIG. 3), the driving circuit CK may be directly fabricated on the flexible substrate SUB and, for example, located between the flexible substrate SUB and a plurality of light-emitting elements LE, but not limited thereto. The active device array may include multiple signal lines (such as multiple scan lines and multiple data lines, etc.) and multiple active elements electrically connected to the multiple signal lines, such as multiple thin film transistors, but is not limited thereto. According to different requirements, the active device array may further include other layers or elements, such as one or more insulating layers, multiple power lines, multiple common electrode lines, and/or passive elements, but not limited thereto.

Taking the driving chip as an example (such as the driving circuit CK in FIG. 2; the driving circuit CK2 in FIG. 3), the driving circuit CK may be bonded to the flexible substrate SUB. Taking the driving circuit CK in FIG. 2 as an example, the driving circuit CK may be bonded to the flexible substrate SUB, wherein the driving chip and the plurality of light-emitting elements LE may be located on the same surface of the flexible substrate SUB. In some embodiments, the driving circuit CK in FIG. 2 is not a whole layer as shown in the figure, but driving chips which may drive multiple light-emitting elements LE. Taking the second driving circuit CK2 in FIG. 3 as an example, the driving circuit CK and the plurality of light-emitting elements LE may be located on opposite surfaces of the flexible substrate SUB, but are not limited thereto.

Referring to FIG. 3 for further explanation, the driving circuit CK may include a first driving circuit CK1 and a second driving circuit CK2, wherein the first driving circuit CK1 is on the same side as the plurality of light-emitting elements LE, and the second driving circuit CK2 is on a different side from the plurality of light-emitting elements LE. The first driving circuit CK1 may include an active device array, and the second driving circuit CK2 may include a driving chip. Although not shown, the first driving circuit CK1 and the second driving circuit CK2 may be electrically connected together through conductive lines (for example, a plurality of conductive vias penetrating the flexible substrate SUB or a plurality of lines disposed on a side wall surface of the flexible substrate SUB).

In some embodiments, as shown in FIG. 2, a printed circuit board may be provided below the flexible substrate SUB. As shown in FIG. 3, a printed circuit board may be provided between the flexible substrate SUB and the second driving circuit CK2.

The plurality of light-emitting elements LE may include a plurality of light-emitting diodes (LEDs), a plurality of organic light-emitting diodes (OLEDs), a plurality of sub-millimeter light-emitting diodes (mini LED), multiple micro LEDs or multiple quantum dot LEDs. According to different requirements, the plurality of light-emitting elements LE may include a plurality of light-emitting elements of different colors or a plurality of light-emitting elements of the same color. For example, when multiple light-emitting elements LE are used as display pixels, the multiple light-emitting elements LE may include multiple red light-emitting elements, multiple green light-emitting elements, and multiple blue light-emitting elements, but are not limited thereto. On the other hand, when multiple light-emitting elements LE are used as backlights, the multiple light-emitting elements LE may include multiple light-emitting elements of the same color, such as multiple white light-emitting elements or multiple blue light-emitting elements, but are not limited thereto. Multiple light-emitting elements LE may be directly fabricated on the flexible substrate SUB or bonded to the flexible substrate SUB through conductive elements (not shown, such as solder balls, conductive adhesive, or anisotropic conductive films).

The first curved unit C1 may be provided to carry and/or support the first electronic element E1. The material of the first curved unit C1 includes, for example, glass, plastic, or metal, but is not limited thereto. In addition, the light transmittance of the first curved unit C1 is not limited, that is to say, the first curved unit C1 may be a light-transmissive unit, a semi-transparent unit or an opaque unit. When the first curved unit C1 is a semi-transparent unit or an opaque unit, the first curved unit C1 may be disposed behind the first electronic element E1 to shield the display screen less. On the other hand, when the first curved unit C1 is a light-transmissive unit, the first curved unit C1 may be disposed in front of or behind the first electronic element E1.

The curved surface SC of the first curved unit C1 is provided to set the first electronic element E1. Through the flexibility of the first electronic element E1, the first electronic element E1 disposed on the curved surface SC may bend in compliance with the curved surface SC to maintain or have a curvature radius consistent with the curved surface SC. The first electronic element E1 may be disposed on the curved surface SC through an adhesive layer or other mechanisms, which is not limited thereto. According to different requirements, the curved surface SC of the first curved unit C1 may be a concave surface with a thin center and a thick periphery, a convex surface with a thick center and a thin periphery, or a combination of the above. Furthermore, the curved surface SC may have one or more curvature radii.

The plane surface SP of the first curved unitC1 is relative to the curved surface SC of the first curved unit C1. In some embodiments, the first curved unit C1 may be used alone to provide structural support for the first electronic element E1, as shown in FIG. 1, but is not limited thereto. In other embodiments, although not shown in FIG. 1, the electronic device may further include a fixing bracket and a plurality of fasteners, and the plane surface SP of the first curved unit C1 (and the plane surface SP of the second curved unit C2) may be fixed to the fixing bracket to provide structural support through a plurality of fasteners.

By maintaining the curvature radius of the first electronic element E1 through the curved surface SC of the first curved unit C1, in addition to achieving the required curved surface shape, it is also possible to improve the problem of deterioration of display quality/visual taste caused by uneven splicing, thereby providing good display quality. In addition, by designing the surface of the first curved unit C1 opposite to the curved surface SC carrying the first electronic element E1 as a plane, the design helps to improve the convenience of assembly, manufacturing and/or design or improve the yield. Moreover, compared with the design using parallel curved surfaces, the design of using curved surface SC combined with plane surface SP makes it possible to have a large bottom area, which helps to improve the stability. In this way, when the first curved unit C1 is used alone to provide structural support for the first electronic element E1, the probability of the first curved module M1 being inclined by an external force may be reduced.

In addition to the curved surface SC and the plane surface SP, the first curved unit C1 may also include a plurality of side wall surfaces SS. After the second curved module M2 is spliced to the first curved module M1, a side wall surface SS of the first curved unit C1 facing the second curved module M2 may be in contact with the side wall surface SS of the second curved unit C1 facing the first curved module M1, but the disclosure is not limited thereto. In other embodiments, there may be a gap between the side wall surface SS of the first curved unit C1 facing the second curved module M2 and the side wall surface SS of the second curved unit C1 facing the first curved module M1. This gap may be an air gap, or this gap may be filled with an insulating material, such as an organic insulating material, an inorganic insulating material, or a combination of the above. Examples of organic insulating materials include, for example, polymethylmethacrylate (PMMA), epoxy, acrylic-based resin, silicone, polyimide polymer, or a combination of the above, but the disclosure is not limited thereto. Inorganic insulating materials include, for example, silicon oxide or silicon nitride, but the disclosure is not limited thereto.

The second electronic element E2 and the second curved unit C2 in the second curved module M2 may be designed with reference to the first electronic element E1 and the first curved unit C1 in the first curved module M1, and the details will not be repeated here.

In some embodiments, the curved surface SC of the first curved unit C1 and the curved surface SC of the second curved unit C2 may form a continuous curved surface. For example, during splicing, the curved surface SC of the first curved unit C1 and the curved surface SC of the second curved unit C2 may be aligned with each other. In this way, the first electronic element E1 and the second electronic element E2 respectively provided on the curved surface SC of the first curved unit C1 and the curved surface SC of the second curved unit C2 may also form a continuous curved surface, so that the electronic device 1 may have a good display quality (e.g., provide continuous images).

According to different requirements, the electronic device 1 may include two curved modules or more. Taking FIG. 1 as an example, the electronic device 1 may further include a third curved module M3, a fourth curved module M4, a fifth curved module M5 and a sixth curved module M6, wherein the first to sixth curved modules M1 to M6 are spliced in pairs with respect to each other in a clockwise direction, for example. The electronic elements (such as the third electronic element E3, the fourth electronic element E4, the fifth electronic element E5 or the sixth electronic element E6) and the curved units (such as the third curved unit C3, the fourth curved unit C4, the fifth curved unit C5 or the sixth curved unit C6) in the respective curved modules (such as the third curved module M3, the fourth curved module M4, the fifth curved module M5 or the sixth curved module M6) may be designed with reference to the first electronic element E1 and the first curved unit C1 in the first curved module M1, and the details are not repeated herein.

Although six curved modules (including the first curved module M1 to the sixth curved module M6) are shown in FIG. 1, the six curved modules have the same dimension (such as arc length, maximum thickness, central angle, etc.) and shape, and the six curved modules form a ring-shaped curved module (for example, a circular display), but the disclosure is not limited thereto. According to different requirements, the electronic device may include a different number of curved modules, and the plurality of curved modules may have different dimensions (for example, one or more of the arc length, maximum thickness, and central angle may be different) and/or shapes. In addition, multiple curved modules may form a display of different shapes, such as a display with a non-closed ring shape, a wave shape, a C shape, a spherical shape or a combination of multiple shapes.

In some embodiments, the curved unit in the curved module may be designed in a way to increase the splicing methods of curved modules. For example, as shown in FIG. 4, the two opposite side wall surfaces SS of the curved unit may be respectively formed with a convex portion P1 and a concave portion D1, wherein the convex portion P1 and the concave portion D1 have complementary shapes, so that the convex portion P1 of the curved unit may be embedded into the concave portion D1 of another curved unit (not shown) so as to realize splicing in a horizontal direction. In addition, the top surface ST and the bottom surface SB of the curved unit may be respectively formed with a convex portion P2 and a concave portion D2, wherein the convex portion P2 and the concave portion D2 have complementary shapes, so that the convex portion P2 of the curved unit may be embedded into the concave portion D2 of another curved unit (not shown), so as to realize splicing in a longitudinal direction (such as direction Z). It should be understood that the shapes of various convex portions and various concave portions in FIG. 4 are only illustrated for exemplary purpose, and the present disclosure is not limited thereto. Moreover, the shape and/or size of the convex portion P1 may be the same as or different from the shape and/or size of the convex portion P2. Correspondingly, the shape and/or size of the concave portion D1 may be the same as or different from the shape and/or size of the concave portion D2. Furthermore, the splicing methods of curved modules may also include pasting, buckling, magnetic attraction or other suitable methods, and the disclosure may not be limited thereto. In some embodiments (not shown), in addition to the above designs, the splicing methods of curved modules may also include splicing from the direction Z, and the disclosure provides no limitation to the splicing methods.

In various curved modules, the relative arrangement relationship and/or size relationship between the electronic element and the curved unit may be changed according to actual needs. The first curved module M1 is described below as an example, but other curved modules may be changed as follows. In some embodiments, as shown in FIG. 1, the area of the first electronic element E1 may be equal to the area of the curved surface SC, and the first electronic element E1 may fully cover the curved surface SC of the first curved unit C1, but is not limited thereto. In other embodiments, as shown in FIG. 5, the area of the first electronic element E1 may be greater than the area of the curved surface SC, and the first electronic element E1 may fully cover the curved surface SC of the first curved unit C1, but is not limited thereto. In some embodiments, as shown in FIG. 6, the area of the first electronic element E1 may be less than the area of the curved surface SC, and the first electronic element E1 may cover only part of the curved surface SC of the first curved unit C1, but is not limited thereto. In yet other embodiments, as the electronic device 1A shown in FIG. 7, the area of the first electronic element E1 may be equal to the area of the curved surface SC, wherein the first electronic element E1 and the first curved unit C1 may be deviated by a distance, so that after the multiple curved modules are spliced together, the electronic element in each curved module further partially overlaps with the curved unit in the adjacent curved module. Taking FIG. 7 as an example, the first electronic element E1 in the first curved module M1 not only partially overlaps with the first curved unit C1 but also partially overlaps with the fifth curved unit C5, and the same applies to other electronic elements; related details are not repeated herein.

In some embodiments, as shown in FIG. 8, in addition to including a plurality of curved modules M, the electronic device 1B may further include a planar module N, wherein the planar module N is spliced together with a plurality of curved modules M to form a display with a non-closed ring shape or a display with a C shape.

In some embodiments, as shown in FIG. 9, the electronic device may further include a fixing bracket BK to provide structural support. For ease of identification, FIG. 9 schematically shows that the front half of the fixing bracket BK is assembled with a curved module M and the rear half is not assembled with the curved module M, and FIG. 9 further shows a curved module M that has not yet been assembled to the fixing bracket BK and multiple fasteners F disposed on the curved module M.

As shown in FIG. 9, the electronic device 1C may include N curved modules M, fixing brackets BK, and multiple fasteners F. N is a positive integer greater than 2 (nine curved modules M are schematically shown in FIG. 9). Each of the N curved modules includes an electronic element E and a curved unit C, and the curved unit C includes a curved surface SC and a plane surface SP. Each plane surface SP is fixed to the fixing bracket BK through at least one of the plurality of fasteners F, and the N curved modules M form a ring-shaped curved module.

The fixing bracket BK is, for example, a frame including a plurality of straight bars, such as a fixing truss, but is not limited thereto. The material of the fixing bracket BK may include metal, alloy, other materials that help to dissipate heat or have a structural support strength, or a combination of the above, but is not limited thereto. Through the design of plane surface SP of the curved unit C, a surface of the fixing bracket BK used to carry the curved unit C may be flat, thus helping to improve the convenience of assembly, production and/or design or improve the yield rate.

The plurality of fasteners F include, for example, magnets, screws, adhesive members, position-adjustable functional members, or a combination of the above, but are not limited thereto. In some embodiments, the plane surface SP of each curved unit C may be fixed to the fixing bracket BK through multiple fasteners F (four are shown in FIG. 9) to improve flatness or adhesion, but is not limited thereto.

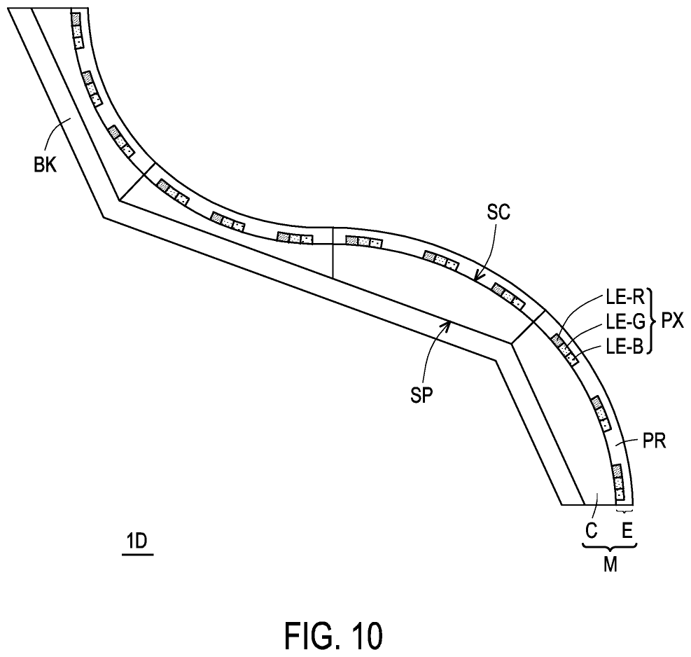

In some embodiments, as shown in FIG. 10, the plurality of curved modules M in the electronic device 1D may be fixed to the fixing bracket BK through a plurality of fasteners (not shown), and the plurality of curved modules M form a display with an irregular shape. In FIG. 10, each electronic element E includes a plurality of pixels PX and a protective layer PR. Each pixel PX includes a red light-emitting element LE-R, a green light-emitting element LE-G and a blue light-emitting element LE-B, and the protective layer PR covers multiple pixels PX. However, it should be understood that each electronic element E may also include other elements or layers, such as the aforementioned flexible substrate SUB and driving circuit CK, but is not limited thereto.

By splicing multiple curved modules M through the fixing bracket BK, the spacing between the minimum display units (such as pixels PX) in adjacent curved modules M may be kept consistent to achieve a large-area continuous display effect.

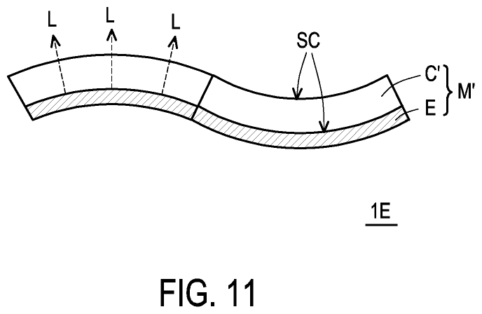

In some embodiments, as shown in FIG. 11, in the electronic device 1E, the electronic element E is, for example, a transparent display panel, and the curved unit C′ is, for example, a light-transmissive unit. The curved unit C′ may be disposed in front of electronic element E, that is, curved unit C′ may be disposed on the light-emitting side of the electronic element E. The light L output from the electronic element E may penetrate the curved unit C′ and be output from the curved module M′. In addition, the two opposite surfaces of the curved unit C′ may both be curved surfaces SC.

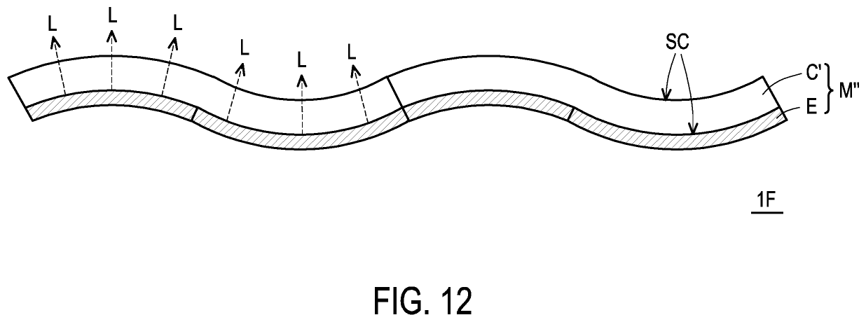

In some embodiments, as shown in FIG. 12, in the electronic device 1F, each curved module M″ may include multiple electronic elements E (two are schematically shown in FIG. 12) and one curved unit C′, and multiple electronic elements E are disposed together on one curved unit C′.

In summary, in the embodiments of the present disclosure, by maintaining the curvature radius of the electronic element through the curved surface of the curved unit, in addition to achieving the required curved surface shape, it is also possible to improve the problem of deterioration of display quality/visual taste caused by uneven splicing, thereby providing good display quality.

The above embodiments are only used to illustrate the technical solution of the present disclosure, but not to limit it; although the present disclosure has been described in detail with reference to the foregoing embodiments, those with ordinary knowledge in the technical field should understand that: the technical solutions described in the foregoing embodiments can still be modified, or some or all of the technical features can be equivalently replaced; and these modifications or substitutions do not deviate the essence of the corresponding technical solutions from the technical solutions of the embodiments of the present disclosure.

Although the embodiments of the present disclosure and their advantages have been disclosed above, it should be understood that anyone with ordinary knowledge in the art can make changes, substitutions and modifications without departing from the spirit and scope of the present disclosure, and the features of various embodiments can be freely mixed and replaced with each other to form other new embodiments. In addition, the protection scope of the present disclosure is not limited to the processes, machines, manufacturing, material compositions, devices, methods and steps in the specific embodiments described in the specification. Anyone with ordinary knowledge in the relevant technical field can understand from the disclosure that processes, machines, manufacturing, material compositions, devices, methods and steps currently or developed in the future may be used according to the present disclosure as long as they can perform substantially the same functions or obtain substantially the same results in the embodiments described herein. Therefore, the protection scope of the present disclosure includes the above-mentioned processes, machines, manufacturing, material compositions, devices, methods and steps. In addition, each claim constitutes an individual embodiment, and the protection scope of the present disclosure also includes combinations of each claim and embodiment. The scope to be protected by the disclosure shall be determined by the scope of the appended claims.

What is claimed is:

1. An electronic device, comprising:
a first curved module, comprising a first electronic element and a first curved unit; and
a second curved module, spliced to one side of the first curved module and comprising a second electronic element and a second curved unit, wherein the first curved unit and the second curved unit comprise curved surfaces.

2. The electronic device according to claim 1, wherein the first curved unit and the second curved unit comprise curved surfaces and plane surfaces.

3. The electronic device according to claim 2, further comprising:
a fixing bracket; and
a plurality of fasteners, wherein the plane surface of the first curved module and the plane surface of the second curved unit are fixed to the fixing bracket through the plurality of fasteners.

4. The electronic device according to claim 3, wherein the fixing bracket is a frame comprising a plurality of straight bars.

5. The electronic device according to claim 3, wherein the plurality of fasteners comprise magnets, screws, adhesive members, position-adjustable functional members, or a combination of the above.

6. The electronic device according to claim 1, wherein the curved surface of the first curved unit and the curved surface of the second curved unit form a continuous curved surface.

7. The electronic device according to claim 1, wherein the electronic element comprises:
a flexible substrate;
a driving circuit, disposed on the flexible substrate; and
a plurality of light-emitting elements, disposed on the flexible substrate and electrically connected to the driving circuit.

8. The electronic device according to claim 7, wherein the driving circuit comprises:
a first driving circuit, disposed between the flexible substrate and the plurality of light-emitting elements; and
a second driving circuit, wherein the flexible substrate is disposed between the first driving circuit and the second driving circuit.

9. The electronic device according to claim 1, wherein the first curved unit and the second curved unit comprise side wall surfaces, and the side wall surface of the first curved unit is in contact with the side wall surface of the second curved unit.

10. The electronic device according to claim 1, wherein the first electronic element and the second electronic element are transparent display panels, and the first curved unit and the second curved unit are light-transmissive units and are respectively located on light-emitting sides of the first electronic element and the second electronic element.

11. An electronic device, comprising:
N curved modules, and N being a positive integer greater than 2, wherein the N curved modules comprise electronic elements and curved units, and the curved units comprise curved surfaces and plane surfaces;
a fixing bracket; and
a plurality of fasteners, wherein the plane surface is fixed to the fixing bracket through at least one of the plurality of fasteners, and the N curved modules form a ring-shaped curved module.

12. The electronic device according to claim 11, wherein the fixing bracket is a frame comprising a plurality of straight bars.

13. The electronic device according to claim 11, wherein the plurality of fasteners comprise magnets, screws, adhesive members, position-adjustable functional members, or a combination of the above.

14. The electronic device according to claim 11, wherein the electronic element comprises:
a flexible substrate;
a driving circuit, disposed on the flexible substrate; and
a plurality of light-emitting elements, disposed on the flexible substrate and electrically connected to the driving circuit.

15. The electronic device according to claim 14, wherein the driving circuit comprises:
a first driving circuit, disposed between the flexible substrate and the plurality of light-emitting elements; and
a second driving circuit, wherein the flexible substrate is disposed between the first driving circuit and the second driving circuit.

16. The electronic device according to claim 11, wherein the curved unit has a thin center and a thick periphery, a thick center and a thin periphery, or a combination of the above.

17. The electronic device according to claim 11, wherein the plurality of the curved surfaces in the N curved modules form a continuous curved surface.

18. The electronic device according to claim 11, wherein the curved unit further comprises a side wall surface, and a plurality of the side wall surfaces in the N curved modules are in contact with each other in pairs.

19. The electronic device according to claim 18, wherein the two side wall surfaces that are opposite to each other in the N curved modules are respectively formed with a convex portion and a concave portion, and the convex portion and the concave portion have complementary shapes.

20. The electronic device according to claim 11, wherein the curved unit further comprises a side wall surface, and a plurality of the side wall surfaces in the N curved modules are spliced together by means of adhesion, buckling or magnetic attraction.
